(19) United States
(12) Patent Application Publication
(10) Pub. No.: US 2009/0051410 A1
(43) Pub. Date: Feb. 26, 2009

(54) Integrated powered device (PD) and physical layer (PHY) chip

(75) Inventor: Asif Hussain, Tustin, CA (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 11/902,469

(22) Filed: Sep. 21, 2007

Related U.S. Application Data
(60) Provisional application No. 60/935,640, filed on Aug. 23, 2007.

(51) Int. Cl. H03H 11/00

(52) U.S. Cl. 327/524

(57) ABSTRACT

An integrated physical layer (PHY) and powered device (PD) chip for use in a Power over Ethernet (PoE) system is provided. Embodiments reduce circuit size and cost and enable improved and novel PoE applications. Embodiments include one or more of a PHY circuit, a PD controller circuit, a DC-DC converter circuit, and an enterprise Internet Protocol (IP) circuit, integrated within a single integrated circuit (IC) chip. Embodiments are implemented using a floating ground design. Embodiments can be implemented using a mixed-voltage or a “voltage island” design or using a multi-die scheme.

### CROSS-REFERENCE TO RELATED APPLICATIONS

The present application claims the benefit of U.S. Provisional Patent Application No. 60/935,640, filed Aug. 23, 2007 (Atty. Docket No. 2875.1490000), which is incorporated herein by reference in its entirety.

### BACKGROUND OF THE INVENTION

1. Field of the Invention

The present invention relates generally to Power over Ethernet (PoE), and more particularly to an integrated powered device (PD) and physical layer (PHY) chip.

2. Background Art

Ethernet communications provide high speed communications between data terminals.

Power over Ethernet (PoE) systems enable power transmission over the same transmission lines that carry data in an Ethernet. Generally, power is generated at a Power Source Equipment (PSE) side of the PoE system and is carried over the data transmission lines to a Powered Device (PD) side of the PoE System.

A PSE controller is typically used at the PSE side to enable power management functions of the PD. For example, a PSE controller may be used to detect whether a valid PD device is active and to manage power flow to the PD. Further, at either side of a PoE system, a transceiver physical layer (PHY) is available to transmit and receive data over the transmission lines.

Conventional PoE systems use separate PSE/PD and PHY chips. In other words, the PHY and PSE chips are conventionally separate, and the PHY and PD chips are conventionally separate. This, however, typically results in increased circuit size and cost and is less practical to enable enhanced and novel PoE applications.

There is a need therefore for improved PoE system designs, so that further chip integration can occur.

### BRIEF SUMMARY OF THE INVENTION

An integrated physical layer (PHY) and powered device (PD) chip for use in a Power over Ethernet (PoE) system is provided herein. Embodiments reduce circuit size and cost and enable improved and novel PoE applications.

Embodiments include one or more of a PHY circuit, a PD controller circuit, a DC-DC converter circuit, and an enterprise Internet Protocol (IP) circuit, integrated within a single integrated circuit (IC) chip. The enterprise IP circuit may include one or more of data, voice, and video circuitry. For example, the enterprise IP circuit may include one or more of IP phone circuitry, IP camera circuitry, wireless local area network (WLAN) access point circuitry, and WLAN router circuitry.

Embodiments are implemented using a floating ground design. Accordingly, the IC chip remains isolated from a chassis ground. Embodiments can be implemented using a multi-die process.

Further embodiments, features, and advantages of the present invention, as well as the structure and operation of the various embodiments of the present invention, are described in detail below with reference to the accompanying drawings.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 is an overview of a Power over Ethernet (PoE) system.

FIG. 2 is a more detailed view of a PoE system.

FIG. 3 is an example that illustrates an electrical strength test used to test the isolation between a power source equipment (PSE) and the chassis ground.

FIG. 4 illustrates an example scenario that violates the IEEE isolation requirement.

FIG. 5 illustrates an example PoE system that uses an integrated PD and PHY chip.

FIG. 6 illustrates an example embodiment of an integrated PD and PHY chip.

FIG. 7 illustrates an example embodiment of an integrated PD and PHY chip.

FIG. 8 illustrates an example embodiment of an integrated PD and PHY chip.

The present invention will be described with reference to the accompanying drawings. Generally, the drawing in which an element first appears is typically indicated by the leftmost digit(s) in the corresponding reference number.

### DETAILED DESCRIPTION OF EMBODIMENT(S)

### Overview

An integrated physical layer (PHY) and powered device (PD) chip for use in a Power over Ethernet (PoE) system is provided herein. Embodiments reduce circuit size and cost and enable improved and novel PoE applications.

Embodiments include one or more of a PHY circuit, a PD controller circuit, a DC-DC converter circuit, and an enterprise Internet Protocol (IP) circuit, integrated within a single integrated circuit (IC) chip. The enterprise IP circuit may include one or more of data, voice, and video circuitry. For example, the enterprise IP circuit may include one or more of IP phone circuitry, IP camera circuitry, wireless local area network (WLAN) access point circuitry, and WLAN router circuitry. The DC-DC converter circuit may be a Pulse Width Modulator (PWM) controller which requires an external Mosfet for flyback topology.

Embodiments are implemented using a floating ground design. Accordingly, the IC chip remains isolated from a chassis ground of the PoE system. Embodiments can be implemented using a mixed-voltage or a “voltage island” design.

### Introduction

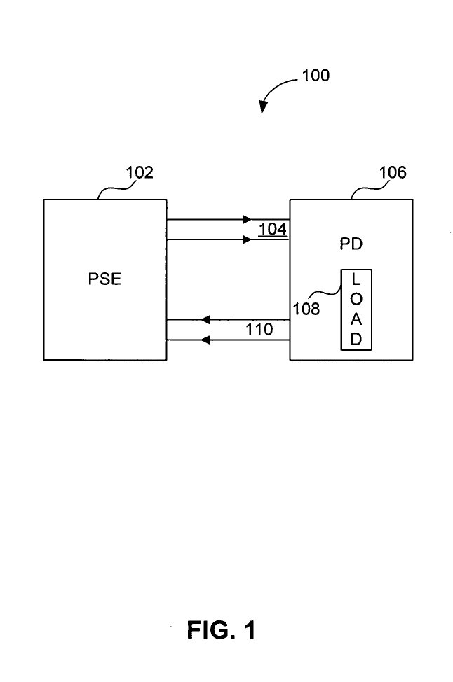

FIG. 1 illustrates a high level diagram of a conventional Power over Ethernet (PoE) system 100 that provides DC power over a common data communications medium. Referring to FIG. 1, power source equipment 102 provides DC power over conductors 104, 110 to a powered device (PD) 106 having a representative electrical load 108. Accordingly, the power transfer between the PSE 102 and the PD 106 occurs simultaneously with the exchange of high speed data over the conductors 104, 110. In one example, the PSE 102 when used with a switching and PHY chip is a data switch having multiple ports that is communicating with one or more PD devices, such as Internet phones, wireless access points, etc.

The conductor pairs 104 and 110 can carry high speed differential data communications. In one example, the conductor pairs 104 and 110 each include one or more twisted wire pairs, or any other type of cable or communications media capable of carrying the data transmissions and DC power transmissions between the PSE and PD. In Ethernet communications, the conductor pairs 104 and 110 can include multiple twisted pairs, for example four twisted pairs for 1 Gigabit Ethernet. In 10/100 Ethernet, only two of the four pairs carry data communications, and the other two pairs of conductors are unused. Herein, conductor pairs may be referred to as Ethernet cables or communication links or structured cabling for ease of discussion. The conductor pairs may be CAT-5 cable for example.

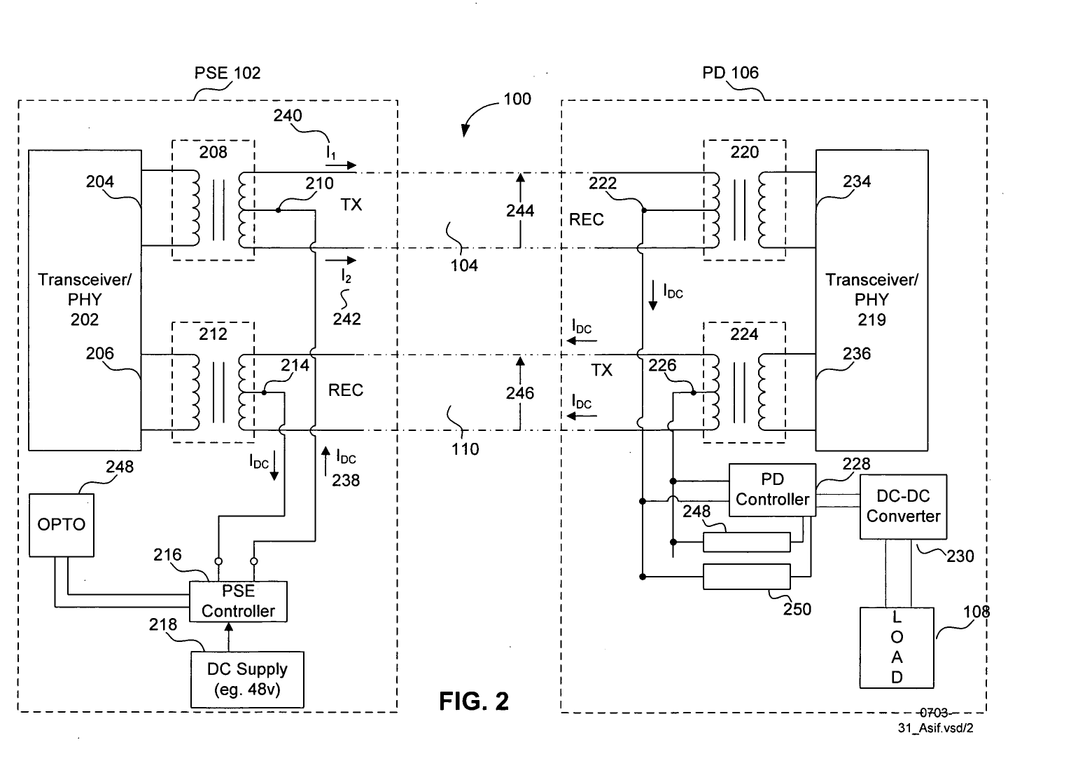

FIG. 2 provides a more detailed circuit diagram of the PoE system 100, where PSE 102 provides DC power to PD 106 over conductor pairs 104 and 110. PSE 102 includes a transceiver physical layer device (or PHY) 202 having full duplex transmit and receive capability through differential transmit port 204 and differential receive port 206. (Herein, transceivers may be referred to as PHYs.) A first transformer 208 couples high speed data between the transmit port 204 and the first conductor pair 104. Likewise, a second transformer 212 couples high speed data between the receive port 206 and the second conductor pair 110. The respective transformers 208 and 212 pass the high speed data to and from the transceiver 202, but isolate any low frequency or DC voltage from the transceiver ports, which may be sensitive to large voltage values.

The first transformer 208 includes primary and secondary windings, where the secondary winding (on the conductor side) includes a center tap 210. Likewise, the second transformer 212 includes primary and secondary windings, where the secondary winding (on the conductor side) includes a center tap 214. The DC output voltage is applied across the respective center taps (e.g. 210, 214) of the transformers 208 and 210 on the conductor side of the transformers. An example DC output voltage for the DC supply 218 is 48 volts, but other voltages could be used depending on the voltage/power requirements of the PD 106 or as per the applicable standard.

The PSE 102 further includes a PSE controller 216 which performs the power management functions based on the dynamic needs of the PD 106. More specifically, the PSE controller 216 measures the voltage, current, and temperature, etc so as to characterize the power requirements of the PD 106.

Further, the PSE controller 216 detects and validates a compatible PD, determines a power classification signature for the validated PD, supplies power to the PD, monitors the power, and reduces or removes the power from the PD when the power is no longer requested or required. During detection, if the PSE finds the PD to be non-compatible, the PSE can prevent the application of power to that PD device, protecting the PD from possible damage. The IEEE has imposed standards on the detection, power classification, and monitoring of a PD by a PSE in the IEEE 802.3™ standard, which is incorporated herein by reference.

Still referring to FIG. 2, the contents and functionality of the PD 106 will now be discussed. The PD 106 side includes a transceiver physical layer device 219 having full duplex transmit and receive capability through differential transmit port 236 and differential receive port 234. A third transformer 220 couples high speed data between the first conductor pair 104 and the receive port 234. Likewise, a fourth transformer 224 couples high speed data between the transmit port 236 and the second conductor pair 110. The respective transformers 220 and 224 pass the high speed data to and from the transceiver 219, but isolate any low frequency or DC voltage from the sensitive transceiver data ports.

The third transformer 220 includes primary and secondary windings, where the secondary winding (on the conductor side) includes a center tap 222. Likewise, the fourth transformer 224 includes primary and secondary windings, where the secondary winding (on the conductor side) includes a center tap 226. The center taps 222 and 226 supply the DC power carried over conductors 104 and 106 to the representative load 108 of the PD 106, where the load 108 represents the dynamic power draw needed to operate PD 106. A DC-DC converter 230 may be optionally inserted before the load 108 to step down the voltage as necessary to meet the voltage requirements of the PD 106. Further, multiple DC-DC converters 230 may be arrayed in parallel to output multiple different voltages (e.g. 3 volts, 5 volts, 12 volts) to supply different loads 108 of the PD 106.

The PD 106 further includes a PD controller 228 that monitors the voltage and current on the PD side of the PoE configuration. The PD controller 228 further provides the necessary impedance signatures on the return conductor 110 during initialization, so that the PSE controller 216 will recognize the PD as a valid PoE device, and be able to classify its power requirements. FIG. 2 also illustrates a signature resistor 248 and a classification resistor 250 connected to PD 106. Signature resistor 248 is used to validate the PD 106, and the classification resistor 250 is used for classifying PD 106 and to limit current for classification.

During ideal operation, a direct current (IDC) 238 flows from the PSE Controller 216 through the first center tap 210, and divides into a first current (I1) 240 and a second current (I2) 242 that are carried over conductor pair 104. The first current (I1) 240 and the second current (I2) 242 then recombine at the third center tap 222 to reform the direct current (IDC) 238 so as to power PD 106. On return, the direct current (IDC) 238 flows from PD 106 through the fourth center tap 226, and divides for transport over conductor pair 110. The return DC current recombines at the second center tap 214, and returns to the DC power supply 218.

As discussed above, data transmission between the PSE 102 and the PD 106 occurs simultaneously with the power as described above. Accordingly, a first communication signal 244 and/or a second communication signal 246 are simultaneously differentially carried via the conductor pairs 104 and 110 between the transceivers or PHY of PSE 102 and the PD 106. It is important to note that the communication signals 244 and 246 are differential signals that ideally are not effected by the DC power transfer described above. However, the signaling used by the PSE controller is based on common mode signaling so it does not interfere with data transmission.

In order to conduct its management and control of PD 106, PSE 102 analyzes certain characteristics of PD 106, and the system as a whole, based on measurements taken at PD 106. Based on those characteristics, PSE 102 can determine certain attributes of PD 106 as well as attributes of the system. Example attributes determined by PSE 102 can include, but are not limited to, the following: valid device detection, power classification, disconnect information, short circuit detection, PD load variations, various current measurements, overload conditions, and inrush conditions.

### Integrated Powered Device (PD) and PHY Chip

Conventional PoE systems use separate PSE/PD and PHY chips. However, integrating the PSE/PD and the PHY chip would be desirable to reduce circuit size and cost and to enable improved and novel PoE applications.

In the teachings herein, several example embodiments for integrating the PD and the PHY chip are provided. These embodiments are provided for the purpose of illustration and are not limiting of the scope of the present invention.

While embodiments of the present invention can be extended to the integration of the PSE and PHY chip, current standard requirements preclude the integration of the PSE and the PHY chip for certain types of applications as will be shown below.

For instance, the IEEE 802.3af isolation requirement necessitates that the PSE provides electrical isolation between the power interface (PI) device circuits, including chassis ground (if any), and all PI leads. Referring to FIG. 2, for example, this entails that PSE Controller 216 provides electrical isolation between DC Supply 218 (PI device circuit) and conductor pairs 104 and 110. For this reason, DC Supply 218, which powers up PSE Controller 216, is generally an isolated power supply, i.e., DC Supply 218 is isolated from the chassis ground.

On the other hand, Transceiver/PHY 202 is powered by a non-isolated power supply, i.e., a power supply that is coupled to the chassis ground. As such, integrating PSE Controller 216 and Transceiver/PHY 202 would violate the IEEE 802.3af isolation requirement.

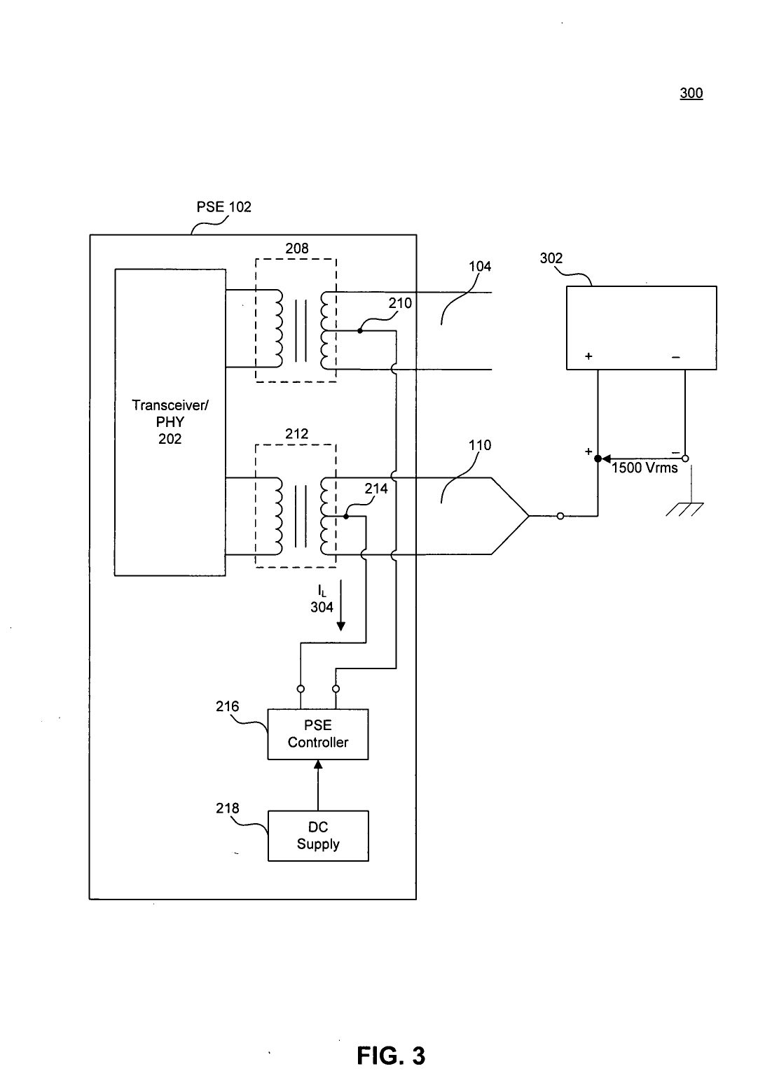

FIG. 3 is an example 300 that illustrates an electrical strength test used to test the isolation between a power source equipment (PSE) and the chassis ground. The electrical strength test shown in FIG. 3 is one of two electrical strength tests specified in Clause 33.4.1 of IEEE 802.3af. As illustrated, the test includes coupling together all of the one or more twisted wire pairs in either of conductor pairs 104 and 110 to form a single node; applying a voltage equivalent to 1500 Vrms (relative to the chassis ground) at 50-60 Hz for sixty seconds at the formed node; and measuring using an amp meter 302 a leakage current I_{L} 304.

The value of the measured leakage current I_{L} 304 determines whether isolation between PSE Controller 216 and the chassis ground is in accordance with the requirements set in IEEE 802.3af.

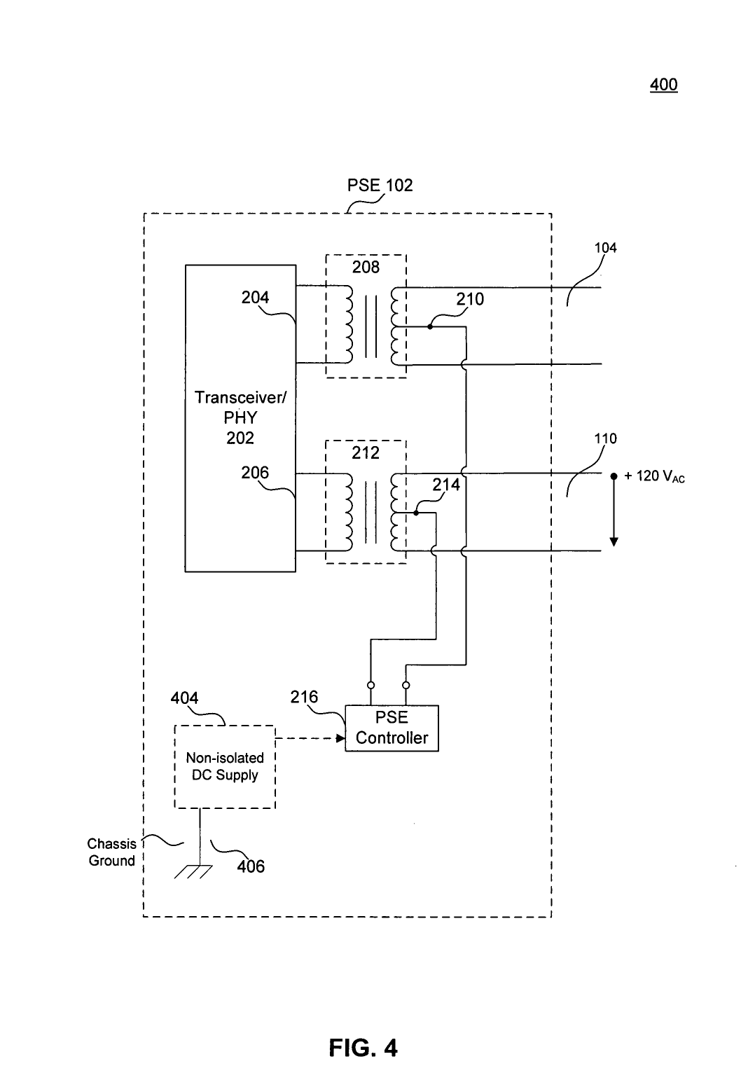

FIG. 4 illustrates an example scenario 400 where PSE Controller 216 is coupled to a non-isolated DC Supply 404 (coupled to chassis ground 406) in violation of the IEEE isolation requirement.

Accordingly, when an AC voltage (e.g., 120 V_{AC}) is inadvertently placed across either of conductor pairs 104 and 110, the resulting current has a flow path to chassis ground 406 via PSE Controller 216, causing damage to any low-voltage circuits on the PSE side, including PSE Controller 216 and Transceiver/PHY 202. Another scenario with similar potential hazards is also created when PSE Controller 216 and Transceiver/PHY 202 are integrated within the same circuit.

However, while the integration of the PSE and the PHY chip are precluded on the PSE side due to the isolation requirement, the lack of similar standard requirements on the PD side can be exploited to realize such integration of the PD and the PHY chip. Indeed, as IEEE 802.3af does not require the PHY chip on the PD side to be coupled to the chassis ground, the PD and the PHY chip can be integrated as long as the integrated chip remains isolated from the chassis ground. This can be achieved using a floating ground PD side design, which enables the PD side to receive the high DC voltage (e.g., 48 V) from the PSE without any resulting current flow that could damage low-voltage processes at the PD side.

In the following, example embodiments for integrating the PD and the PHY chip will be provided. These example embodiments are provided for the purpose of illustration and are not limiting of the scope of the present invention.

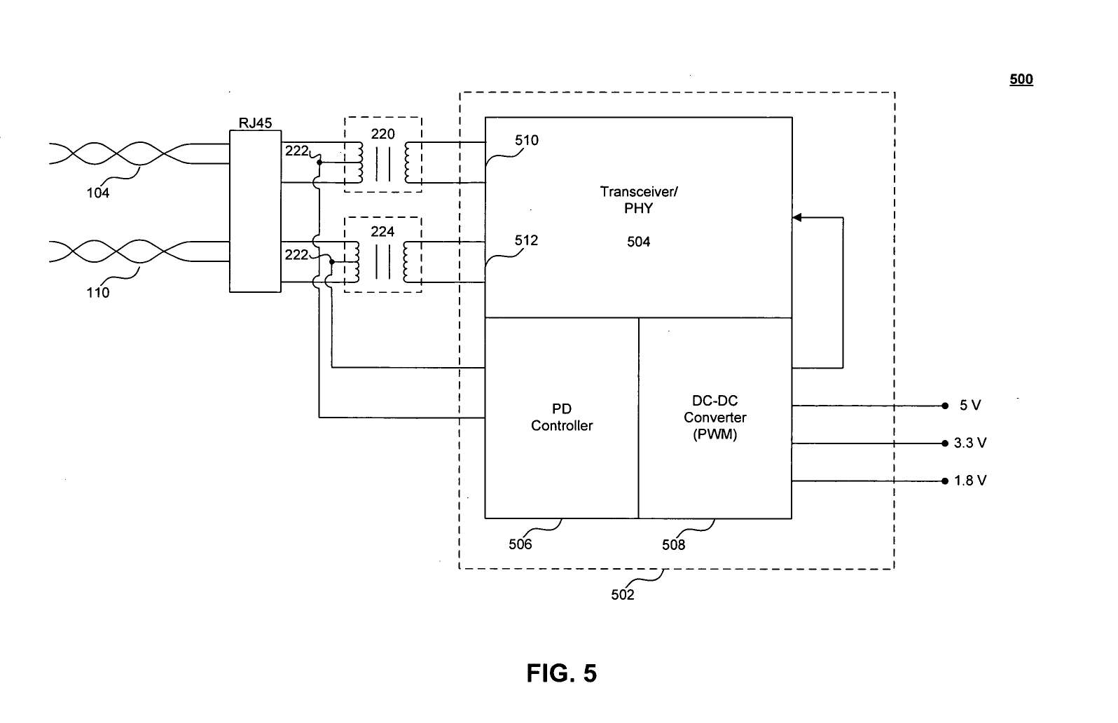

FIG. 5 illustrates an example PoE arrangement 500 that uses an integrated PD and PHY chip 502.

Integrated chip 502 includes a Transceiver/PHY 504, a PD Controller 506, and a DC-DC converter 508. Integrated chip 502 can be implemented using a mixed-voltage design. In an embodiment, a standard CMOS process is modified to operate with the power supply voltages.

Transceiver/PHY 504 includes at least the same functionalities and operates similarly to transceiver/PHY 219 described above with respect to FIG. 2. PD Controller 506 includes at least the same functionalities and operates similarly to PD Controller 228 described above with respect to FIG. 2. DC-DC converter 508 includes at least the same functionalities and operates similarly to DC-DC converter 230 described above with respect to FIG. 2.

Integrated chip 502 also includes a plurality of data ports and power ports. The data ports provide connections to differential receive port 510 and differential transmit port 512 of Transceiver/PHY 504. The power ports provide connections to power input ports of PD controller 506.

Within integrated chip 502, DC-DC Converter 508 steps down the DC voltage carried over conductor pairs 104 and 110 and provides several voltage taps with different levels (e.g., 1.8 V, 3.3 V, 5 V) for use by the PD (not shown in FIG. 5). At the same time, DC-DC Converter 508 provides an appropriate supply voltage to Transceiver/PHY 504.

As noted above, throughout operation, integrated chip 502 is maintained isolated from the chassis ground of the PoE arrangement.

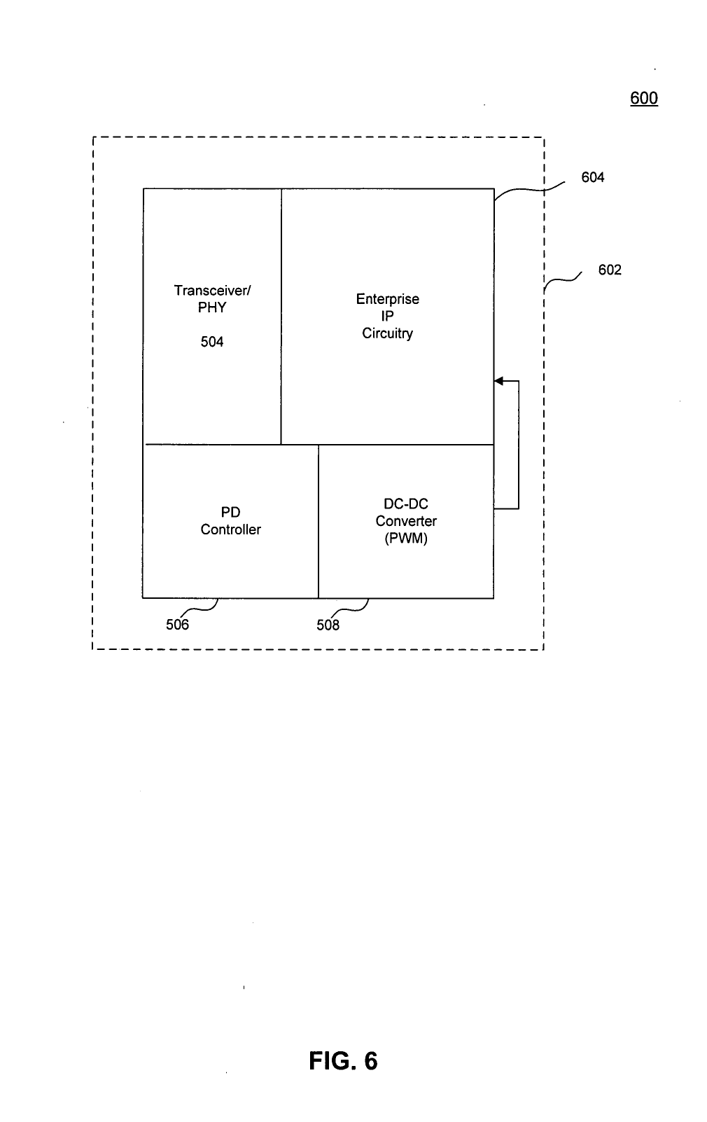

FIG. 6 is an example 600 of another embodiment 602 of the integrated PD and PHY chip. Example embodiment 602 can be used in example PoE arrangement 500.

Example embodiment 602 includes a Transceiver/PHY 504, a PD Controller 506, a DC-DC Converter 508, and Enterprise IP Circuitry 604. For ease of illustration, data and power ports of integrated chip 602 are not shown. Integrated chip 602 can be implemented using a mixed-voltage design using multi-die as an example.

As in example 500, DC-DC Converter 508 operates to step down the DC voltage carried over conductor pairs 104 and 110 and provides an appropriate supply voltage to Transceiver/PHY 504. DC-DC Converter 508 may be a PWM controller using an external Mosfet with flyback topology. However, since the PD, illustrated as Enterprise IP Circuitry 604, is integrated within integrated chip 602, DC-DC Converter 508 does not supply DC voltage taps as in example 500. DC-DC Converter 508 provides an appropriate supply voltage to Enterprise IP Circuitry 604. Other advantages of example embodiment 602 should also be apparent to a person skilled in the art based on the teachings herein, including eliminating any needed external interface/bus circuitry between Transceiver/PHY 504 and Enterprise IP Circuitry 604.

Enterprise IP Circuitry 604 may include any IP-enabled device including, without limitation, data, voice, and/or video devices. For example, Enterprise IP Circuitry 604 may include an IP phone, an IP camera, and/or a WLAN access point/router.

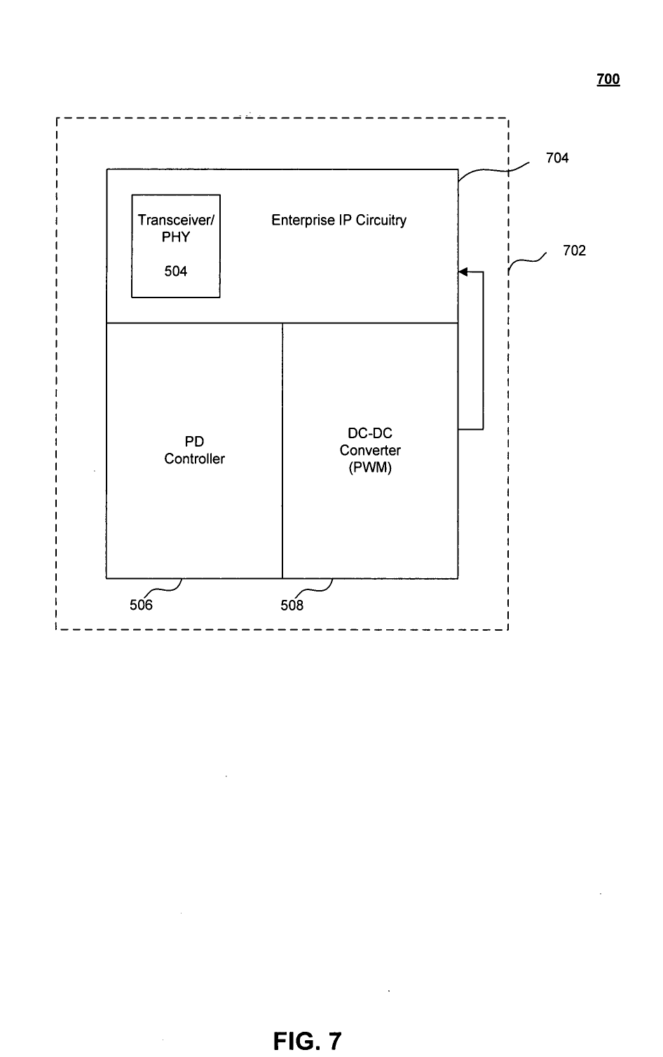

FIG. 7 is an example 700 of another embodiment 702 of the integrated PD and PHY chip. Example embodiment 702 can be used in example PoE arrangement 500. Integrated chip 702 can be implemented using a mixed-voltage design.

Example embodiment 702 is substantially similar to example embodiment 602, described above. One difference is that Transceiver/PHY 504 is embedded within the Enterprise IP Circuitry 704 portion of integrated chip 702. Accordingly, DC-DC Converter 508 needs to provide a single supply voltage to power up Transceiver/PHY 504 and Enterprise IP Circuitry 704, instead of two supply voltages in example embodiment 702. Other advantages of example embodiment 702 should also be apparent to a person skilled in the art based on the teachings herein, including eliminating any needed interface circuitry between Transceiver/PHY 504 and Enterprise IP Circuitry 704.

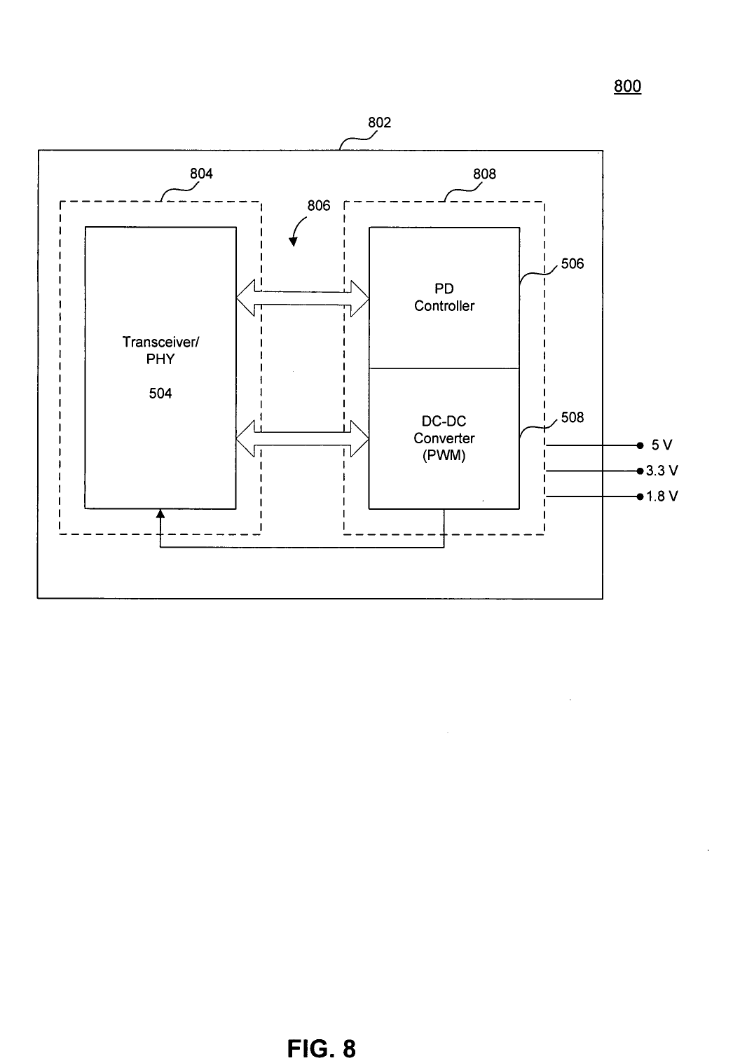

FIG. 8 is an example 800 of another embodiment 802 of the integrated PD and PHY chip. Example embodiment 802 can be used in example PoE arrangement 500.

Example embodiment 802 includes similar integrated components as example embodiment 502. The integrated components operate in a substantially similar fashion as described above with respect to FIG. 5.

However, instead of using a mixed-voltage design, example embodiment 802 is implemented using a “voltage island” design, which partitions components of integrated chip 802 according to similarities in voltage requirements and timing of power states to form voltage islands. As shown in FIG. 8, example embodiment 802 uses two voltage islands 804 and 808 to separate the Transceiver/PHY 504 low-voltage process from the PD Controller 506 and DC-DC Converter 508 higher-voltage process. An interface 806 is then used to enable signal communication between the two voltage islands 804 and 806. Alternatively, a multi-die scheme could be used.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A Power over Ethernet (PoE) system, comprising:
a Power Source Equipment (PSE) module;
a Powered Device (PD) module; and
a plurality of conductor pairs that couple said PSE module and PD module to enable power and data transmission between said PSE module and PD module;
wherein said PD module comprises:
a transceiver physical layer (PHY) circuit;
a PD controller circuit; and
a DC-DC converter circuit;
wherein said PHY circuit, PD controller circuit, and DC-DC converter circuit are integrated within a single integrated circuit (IC) chip.

2. The system of claim 1, wherein said IC chip is isolated from a chassis ground of the system.

3. The system of claim 1, wherein said IC chip is coupled to a floating ground.

4. The system of claim 1, wherein said PD module further comprises:
an enterprise Internet Protocol (IP) circuit integrated within said single IC chip.

5. The system of claim 4, wherein said PHY circuit is embedded within said enterprise IP circuit.

6. The system of claim 4, wherein said enterprise IP circuit includes one or more of data, voice, and video circuitry.

7. The system of claim 6, wherein said enterprise IP circuit includes one or more of IP phone circuitry, IP camera circuitry, Wireless Local Area Network (WLAN) access point circuitry, and WLAN router circuitry.

8. A powered device (PD) module for use in a Power over Ethernet (PoE) system, comprising:
a transceiver physical layer (PHY) circuit;
a PD controller circuit; and
a DC-DC converter circuit;
wherein said PHY circuit, PD controller circuit, and DC-DC converter circuit are integrated within a single integrated circuit (IC) chip; and
wherein said IC chip is isolated from a chassis ground of the PoE system.

9. The PD module of claim 8, wherein said IC chip is coupled to a floating ground.

10. The PD module of claim 9, further comprising:
an enterprise Internet Protocol (IP) circuit integrated within said IC chip.

11. The PD module of claim 10, wherein said enterprise IP circuit includes one or more of data, voice, and video circuitry.

12. The PD module of claim 8, wherein said IC chip includes mixed-voltage circuitry.

13. The PD module of claim 8, wherein said IC chip is partitioned into one or more voltage islands according to voltage requirements of components thereof.

14. The PD module of claim 13, wherein said IC chip includes:
a first voltage island comprising said PHY circuit;
a second voltage island comprising said PD controller circuit and said DC-DC converter circuit; and
an interface that couples said first and second voltage islands.

15. An Internet Protocol (IP) device usable in a Power over Ethernet (PoE) system, comprising:
an integrated transceiver physical layer (PHY), powered device (PD) controller, and DC-DC converter chip; and
an enterprise IP circuit coupled to said integrated chip;
wherein said enterprise IP circuit receives a supply voltage from the DC-DC converter component of said integrated chip and communicates high-speed data via the PHY component of said integrated chip.

16. The IP device of claim 15, wherein said enterprise IP circuit includes one or more of data, voice, and video circuitry.

17. The IP device of claim 15, wherein said enterprise IP circuit includes one or more of IP Phone, IP camera, Wireless Local Area Network (WLAN) access point, and WLAN router.

18. The IP device of claim 15, wherein said integrated chip includes mixed-voltage circuitry.

19. The IP device of claim 15, wherein said integrated chip is partitioned into one or more voltage islands according to voltage requirements of components thereof.

20. The IP device of claim 19, wherein said IC chip includes:
a first voltage island comprising said PHY circuit;
a second voltage island comprising said PD controller circuit and said DC-DC converter circuit; and
an interface that couples said first and second voltage islands.
